(19) United States
(12) Patent Application Publication
(10) Pub. No.: US 2025/0171928 A1
(43) Pub. Date: May 29, 2025

(54) HYBRID COVALENT-VAN DER WAALS SYSTEM 2D HETEROSTRUCTURES BY DATIVE EPITAXY

(71) Applicant: The Research Foundation for The State University of New York, Amherst, NY (US)

(72) Inventors: Hao ZENG, East Amherst, NY (US); Mengying BIAN, Amherst, NY (US)

(21) Appl. No.: 18/842,778

(22) PCT Filed: Mar. 2, 2023
(86) PCT No.: PCT/US23/63610

§ 371 Date: Aug. 29, 2024

Related U.S. Application Data
(60) Provisional application No. 63/315,965, filed on Mar. 2, 2022.

(51) Int. Cl. C30B 29/46; C30B 25/18; C30B 29/68; H01L 21/02; H10D 62/82

(52) U.S. Cl. CPC C30B 29/46; C30B 25/18; C30B 29/68; H01L 21/02568; H10D 62/8281

(57) ABSTRACT

A method for making a two-dimensional heterostructure where one or more van der Waals template precursors may be deposited on a substrate such that a van der Waals template grows on the substrate, and one or more crystal layer precursors may be deposited on a surface of the van der Waals template such that a crystal layer grows on the van der Waals template, wherein the crystal layer is an epitaxial crystal layer. Also provided is an epitaxially-grown two-dimensional heterostructure with at least two components, wherein a plurality of the components engage in dative bonding.

### CROSS REFERENCE TO RELATED APPLICATIONS

This application claims priority to U.S. Provisional Patent Application No. 63/315,965, filed on Mar. 2, 2022, the disclosure of which is incorporated herein by reference.

### STATEMENT REGARDING FEDERALLY SPONSORED RESEARCH

This invention was made with government support under grant number 2042085 awarded by National Science Foundation. The government has certain rights in the invention.

### BACKGROUND OF THE DISCLOSURE

Two-dimensional (2D) semiconductors are the core force of next-generation electronics and optoelectronics, which are expected to exhibit quantum effects and greatly improve the density of the transistor, extending Moore's law. The 2D semiconductor heterostructures produced in the field rely on exfoliation and restacking, which lacks the ability to be scaled up for industrial applications. 2D semiconductor films synthesized by, for example, chemical vapor deposition are usually polycrystalline with defective grain boundaries. It is also a long standing challenge to grow conventional compound semiconductors such as CdSe, GaAs, and GaN into 2D continuous films that are atomically flat, due to their 3D bonding nature.

Two dimensional (2D) heterostructures obtained by stacking van der Waals (vdW) layers have attracted intense interest for fundamental research and applications in electronics, optoelectronics, spintronics, and valleytronics. In particular, moiré superlattices achieved by aligning or twisting individual 2D layers offer an additional degree of freedom for manipulating the electronic structure. It is well known that correlated insulating states, superconductivity, magnetism, and topological helical states can emerge in twisted bilayer graphene moiré superlattices and graphene/hexagonal boron nitride heterostructures. Moiré superlattice exciton states and interlayer valley excitons were also observed in WSe₂/WS₂ and MoSe₂/WSe₂ heterostructures, respectively. However, the conventional exfoliation and stacking approach lacks scalability for practical applications. Recently, 2D vdW heterostructures have been realized by chemical vapor deposition (CVD), such as graphene/hBN, and transition metal dichalcogenide (TMD) heterostructures (e.g., WS₂/MoS₂, SnS₂/MoS₂, and NbTe₂/WSe₂). vdW epitaxy overcomes the constraints of lattice matching and processing compatibility requirements in traditional epitaxial growth. A wide range of materials including 2D, 3D, and organic crystals have been grown by this technique. vdW epitaxy is particularly suitable for synthesizing 2D heterostructures owing to the atomically smooth and dangling bond-free vdW surface. However, because vdW surfaces are chemically inactive, chemical or plasma treatments may be needed to facilitate nucleation, which leads to a defective interface. Moreover, limited success has been achieved for vdW epitaxy of covalent materials with a continuous film morphology instead of discrete domains with misorientations. This is because the weak vdW interaction and the resulting energy landscape as a function of the in-plane orientation angle may not exhibit clearly defined minima, required for high-quality epitaxy.

Moiré superlattices have become promising platforms for studying emergent phenomena, such as strongly correlated physics and non-trivial topology in quantum materials. However, moiré superlattices obtained by exfoliation and restacking via aligning/twisting van der Waals layers are typically small in size and accompanied by gradual spatial modulation or local domain formation.

### SUMMARY OF THE DISCLOSURE

The present disclosure provides epitaxial growth of a hybrid covalent-van der Waals system Cr₅Te₈/WSe₂, with a thickness of Cr₅Te₈ down to a single unit cell and yet a size as large as 50 μm, by chemical vapor deposition. Different from conventional moiré systems, a fully commensurate, single-crystalline 3×3 (Cr₅Te₈)/7×7 (WSe₂) moiré supercrystal over the entire superlattice is achieved, through dative bond formation. This is a conceptually distinct paradigm of thin film epitaxy termed “dative epitaxy,” which can be used to produce two-dimensional superlattices for exploring emergent physics and also address the long-standing challenge of growing two-dimensional covalent materials and heterostructures with high crystal quality for semiconductor and other industrial applications.

### BRIEF DESCRIPTION OF THE FIGURES

For a fuller understanding of the nature and objects of the disclosure, reference should be made to the following detailed description taken in conjunction with the accompanying figures.

FIG. 1. Schematic of the heterostructure by dative bond formation at interface.

FIG. 2. Moire superlattices of Cr₅Te₈/WSe₂, the periodicity of the supercell is 2.3 nm.

FIG. 3. Perfectly square magnetic hysteresis of Cr₅Te₈ implying free of interfacial defect pinning sites; expected to be applicable to CSs.

FIG. 4. Optical and atomic force microscope images of WSe₂ and Cr₅Te₈/WSe₂ heterostructures. a, b, Optical microscope images of monolayer WSe₂ of sizes of ˜200 μm (a) and ˜1 mm (b); c, 2D Cr₅Te₈/WSe₂ heterostructures; d, e Highly aligned Cr₅Te₈ crystals with a thickness of ˜10 nm (d) and 1.4 to 2.8 nm (the dashed lines serve as visual aids to discern the boundaries of 2D crystals) (e) on a single monolayer WSe₂; f, An AFM image of an area of one unit cell thick Cr₅Te₈ crystals; the dashed line shows the boundary between monolayer WSe₂ and sapphire substrate.

FIG. 5. HAADF-STEM analysis of the Cr₅Te₈/WSe₂ moiré superlattice. a, Atomic-resolution HAADF-STEM image showing the moiré pattern of the Cr₅Te₈/WSe₂ heterostructure. b, FFT pattern obtained from (a). The diffraction spots marked by circles: WSe₂ (100); triangles: Cr₅Te₈ (200); squares: examples of self-intercalated Cr atoms matched to trigonal Cr₅Te₈; diamonds: the moiré superlattice. c, d, IFFT images of identically oriented WSe₂ (c) and Cr₅Te₈ (d) lattices obtained from (b). e, Side view along (210) and top view of the atomic model of the Cr₅Te₈/WSe₂ superlattice. f, Simulated diffraction patterns obtained from the atomic model, matching that in (b). g, Experimental and h, simulated HAAD-STEM images showing identical moiré superlattice of Cr₅Te₈/WSe₂.

FIG. 6. Atomic and electronic structure of the Cr₅Te₈/WSe₂ interface. a, Site-decomposed partial DOSs of interfacial Cr (left) and Se (right) sp states for individual Cr₅Te₈, WSe₂ (gray curves) and WSe₂/Cr₅Te₈ (black curves). b, A schematic diagram illustrating the dative bond formation process. c, c-axis projected differential charge density Δp profile along the Te—Cr—Se—W direction. d, Calculated lattice spacing of CrTeₓ as a function of self-intercalated Cr number. e, Cross-sectional iDPC image of the Cr₅Te₈/WSe₂ heterostructure. The arrow in (e) indicates the EELS line scan direction; the box is the area shown in (f). f, A magnified image in (e). The circles mark the atomic columns with weak contrast, which are attributed to interfacial Cr atoms. g, The integrated intensity ratio between Cr L₃ and L₂ edges measured by EELS as a function of position from WSe₂ to Cr₅Te₈ along the red arrow direction in (e). Error bars represent statistical uncertainty of the mean value. h, Raman spectra of monolayer WSe₂ and Cr₅Te₈/WSe₂ heterostructure. Dashed lines: data; solid lines: fittings using Lorentzian function.

FIG. 7. RMCD measurements of Cr₅Te₈ single flakes grown on WSe₂. a, b, c, AFM images of Cr₅Te₈ crystals grown on WSe₂ and d, e, f, the corresponding RMCD hysteresis loops measured at 5 K.

FIG. 8. Epitaxial growth process of Cr₅Te₈/WSe₂ heterostructures and atomic model of Cr₅Te₈. a, A schematic of the epitaxial growth processes of 2D Cr₅Te₈/WSe₂ heterostructures, showing monomer adsorption, desorption, and diffusion. It also shows dative bonding between interfacial Cr (red) and Se atoms (green). b, An atomic model of Cr₅Te₈/WSe₂ superlattice, as viewed along the (100) axis. c, A schematic diagram of the CVD set up for the growth of Cr₅Te₈/WSe₂ heterostructures. d, The heating profiles of the two zones of the two-step CVD growth process.

FIG. 9. Optical microscope images of Cr₅Te₈, WSe₂, Cr₅Te₈/WSe₂ heterostructures and atomic force microscope images. Optical microscope images of a, random oriented Cr₅Te₈ crystals on sapphire substrate, and b, thin Cr₅Te₈ crystals of 1.4 to 2.8 nm on WSe₂ grown on sapphire, which is 2 mm away from the source (Same as FIG. 4e, but with artificially enhanced contrast). c, An optical microscope image and d, the corresponding AFM image of a 2D Cr₅Te₈ crystal with a thickness of 1.4 nm (single unit cell) and the lateral size of ˜46 μm grown on WSe₂ on sapphire. e, A triangular-shaped monolayer WSe₂ crystal on sapphire substrate. f, Part of a monolayer WSe₂ with a lateral dimension of 1 mm. g, Thick (˜10 nm) and dense Cr₅Te₈ 2D crystals grown on WSe₂ on SiO₂, which is 0.2 mm away from the source and h, thin Cr₅Te₈ crystals of one to two unit cells thickness (1.4 to 2.8 nm) on WSe₂ on SiO₂, which is 2 mm away from the source.

FIG. 10. A larger area atomic-resolution HAADF-STEM image of Cr₅Te₈/WSe₂ moiré superlattice. a, b, A HAADF-STEM image of Cr₅Te₈/WSe₂ moiré superlattice and the corresponding FFT pattern obtained from (a). c, d, Selected diffraction point from Cr₅Te₈ and the corresponding iFFT image of Cr₅Te₈. e, f, Selected diffraction point from WSe₂ and the corresponding iFFT image of WSe₂.

FIG. 11. HAADF-STEM images of Cr₅Te₈/WSe₂ moiré superlattices measured at different locations. a, c, e, Atomic-resolution HAADF-STEM images showing the moiré pattern of the Cr₅Te₈/WSe₂ heterostructure from the blue, green, orange region in g. The atomic-resolution HAADF-STEM image of the region shown in red is shown in FIG. 5. b, d, f, The corresponding FFT images of a, c, e, respectively. The moiré superlattice diffraction is marked by diamonds in a. g, Low resolution HAADF-STEM image of a single 2D Cr₅Te₈/WSe₂ heterostructure. h, A cross-sectional HAADF-STEM image of Cr₅Te₈/WSe₂ heterostructure.

FIG. 12. Hypothetical atomic structures and simulated electron diffraction patterns of Cr₅Te₈/WSe₂ heterostructures. a, Cross-sectional view of the atomic model with 9 interfacial Cr atoms per supercell, identical to the number of self-intercalated Cr in between CrTe₂ layers of Cr₅Te₈. b. The corresponding simulated electron diffraction of Cr₅Te₈/WSe₂ heterostructure. c, Cross-sectional view of the atomic model with Te-terminated interface. d. The corresponding simulated electron diffraction of Cr₅Te₈/WSe₂ heterostructure. The lattice periodicity belonging to the commensurate moiré superlattice is absent in both diffraction patterns.

FIG. 13. EELS-STEM of Cr-L_{2,3} and Te-M edge from the bulk and interface. The integrated L₃/L₂ ratio is larger at the interface, suggesting lower valence state of interfacial Cr atoms.

FIG. 14. Raman spectra and PL spectra of monolayer WSe₂ and Cr₅Te₈/WSe₂ heterostructure. Raman spectra of representative a, monolayer WSe₂ and b, Cr₅Te₈/WSe₂ heterostructures measured at room temperature excited at 514 nm (dashed lines). The solid lines are cumulative fitting spectra using Lorentzian functions. c, PL spectra of monolayer WSe₂ and Cr₅Te₈/WSe₂ heterostructure grown on SiO₂/Si substrates were measured at room temperature. The significant decrease of PL intensity in the heterostructure can be attributed to the charge transfer of photo-induced carriers at the interface. Since the predicted Fermi level of Cr₅Te₈ is slightly below the conduction band of WSe₂, the photogenerated electrons at the conduction band of WSe₂ will transfer to Cr₅Te₈, thus quench the PL emission.

FIG. 15. Site-projected densities of states (DOS) of Cr₅Te₈/WSe₂ moiré superlattice compared to those of individual Cr₅Te₈ and WSe₂ layers. Left to right: interfacial Cr sp-states, interfacial Se sp-states, W d-states, W p-states. The red curves show DOS of individual layers, and black curves are DOS of Cr₅Te₈/WSe₂ moiré superlattice. DOSs of the representative sites of Cr₅Te₈/WSe₂ moiré superlattice show that there is a redistribution of electron states, most strongly noticeable for the intercalated Cr site. DOSs of W in Cr₅Te₈/WSe₂ superlattice are very similar to those of WSe₂ monolayer, exhibiting a rigid shift of ˜0.5 eV due to the band alignment across the interface. Fermi energy in the superstructure is close to the conduction band of WSe₂. There is a small charge transfer towards W.

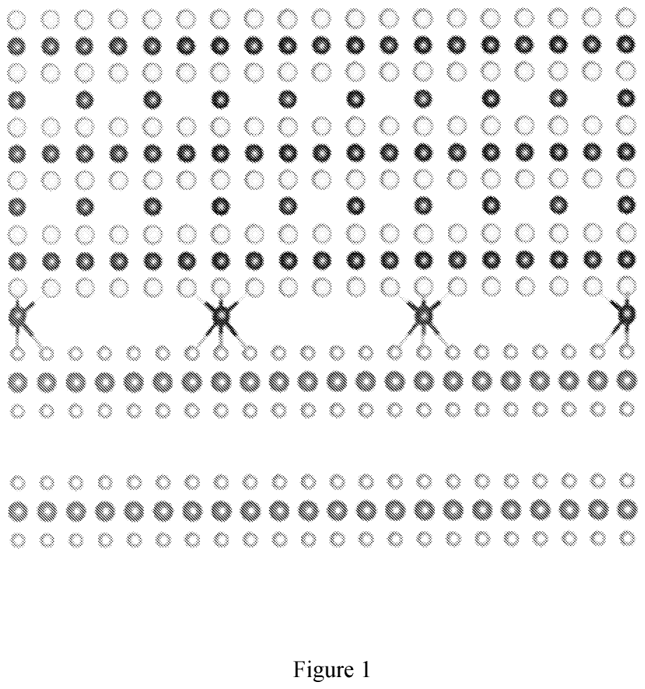

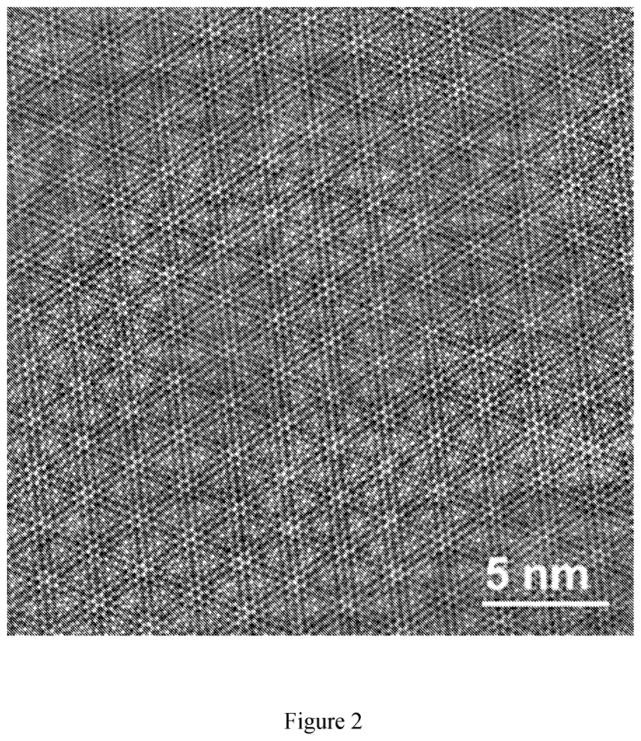

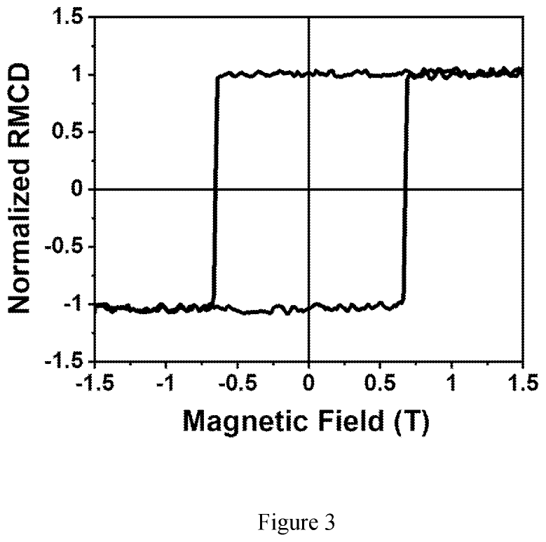

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure.

All ranges provided herein include all values that fall within the ranges to the tenth decimal place, unless indicated otherwise.

The dative epitaxy is an entirely novel paradigm of thin film epitaxial growth, which relies on dative bonding (a special type of covalent bonding) with the prospects of growing wafer-scale two-dimensional semiconductors of a wide range of materials with high crystal quality, free of substrate choices.

Heteroepitaxial growth of compound semiconductors (CSs) such as GaAs and GaN on Si can greatly enhance CMOS. Synthesis of such heterostructures, with the high-quality interfaces needed for transistor applications, remains a significant challenge. The present disclosure provides an advance in the “dative epitaxy” (DE) of heterogeneous 2D materials, to fabricate high quality CS heterostructures on Si and to implement efficient transistors whose high-quality interfaces yield superior performance. These devices should be compatible with the CMOS thermal budget, be scalable to state-of-the-art gate lengths, and ultimately allow manufacture on 300-mm wafers.

Dative Epitaxy (DE) is a new paradigm of epitaxial growth applicable to the synthesis of numerous semiconductors on various substrates. Conceptually distinct from the traditional epitaxial growth of 3D covalent materials, and of van der Waals (vdW) epitaxy of 2D materials, DE takes advantage of an atomically smooth, dangling-bond-free vdW template, with its low surface-diffusion barrier for large-area 2D growth, to pin the atomic registry and crystal orientation needed to realize epitaxial growth. Without intending to be bound by a specific theory, it is considered that the presence of anion lone pair electrons, as in vdW TMDs (MoS₂, WSe₂, etc.) contributes to the dative epitaxy of the present disclosure.

Embodiments of the present disclosure use covalent epitaxy with chemical bonding for fixing the atomic registry and crystal orientation, while circumventing the stringent lattice matching requirements. An advantage to the method of the present disclosure is that it ensures the full flexibility of vdW epitaxy while avoiding its poor orientation control.

Additional advantages of the present disclosure include enabling epitaxial growth of a variety of CSs (e.g. GaAs, GaN, CdTe), its CMOS-compatible substrates, scalability to 300 mm wafer, minimized interfacial defects, and suitability for heterogeneous integration of Si and CSs.

Described is the design and synthesis of hybrid covalent-van der Waals (vdW) system 2D heterostructures by dative epitaxy. This technology may use a two-step chemical vapor deposition (CVD) or physical vapor deposition (PVD) process whereby a layer of vdW material (such as WSe₂ or NbSe₂) is deposited, and serves as a template. The layer of vdW material may be thin (e.g., atomically thin). A covalent semiconductor such as CdSe or GaN can then be deposited. Dative epitaxy is distinctly different from conventional three-dimensional epitaxy with strong covalent bonding or conventional vdW epitaxy where the epilayer has weak interactions with the vdW substrates. In dative epitaxy, the epilayer interact with the vdW template via dative bond, a special covalent bond that has an intermediate strength compared to covalent bonding and vdW binding. Thus, it takes advantage of weak vdW interactions for the facile surface diffusion of precursor molecules to realize large area 2D growth of conventional semiconductors, which is otherwise difficult due to their 3D bonding nature. The present technique also exploits the directional dative bonding at the interface to fix the atomic registry and crystal orientation for epitaxial growth of these 2D semiconductors. The outcome is a monocrystalline atomically thin 2D semiconducting layers epitaxially grown on the vdW templates. By choosing vdW templates matched to the semiconducting materials to form dative bonds, and optimizing the synthesis conditions, a large range of semiconductor materials can be grown as 2D atomic layers. The “dative epitaxy” method of the present disclosure is applicable to a wide range of covalent materials on vdW templates, including 2D semiconductors. This addresses the outstanding challenge of growing large scale 2D semiconductor films with high crystal quality on scalable and industry-compatible substrates. Large scale single crystal 2D semiconductor films free of detrimental grain boundaries and interfacial defects have uniform electrical and mechanical properties, which are advantageous for mass production in semiconductor industrial applications.

The present disclosure provides epitaxially grown atomically thin compound semiconductors at wafer scale for electronics and optoelectronic applications such as photodetectors, sensors, field effect transistors, and light emitting diodes; epitaxially grown superconducting thin films and heterostructures used for superconducting nanowire single photon detectors and superconducting qubits.

The present disclosure has several advantages, including: deposition speed is much higher than molecular-beam epitaxy (MBE); very low density of interface defects; the ability to achieve atomically thin layers down to a single unit cell; the ability to achieve dangling-bond-free surface. All these advantages ensure high electronic quality of the realized films. The method does not require special substrates lattice matched to the material to be deposited, thus allows any substrate (e.g., Si which is CMOS compatible or amorphous substrates). It also allows any material to be epitaxially grown, which is otherwise not possible due to lack of matching substrates.

In an aspect, the present disclosure provides a method for making a two-dimensional heterostructure. One or more van der Waals template precursors may be deposited on a substrate such that a van der Waals template grows on the substrate. One or more crystal layer precursors may be deposited on a surface of the van der Waals template such that a crystal layer grows on the van der Waals template, wherein the crystal layer is an epitaxial crystal layer.

In various embodiments of the present disclosure, the van der Waals template may be compositions having a formula of MX₂; where M is chosen from Ti, Hf, V, Nb, Ta, Mo, W, Re, Co, Pt, and Zr and X is chosen from S, Se, and Te. For example, the van der Waals template may be or may include WSe₂, WS₂, WTe₂, NbSe₂, MoS₂, MoSe₂, MoTe₂, VSe₂ or the like.

In various embodiments of the present disclosure, the vdW template can be further transferred onto other substrates for the growth of heterostructures. This allows the covalent epi-layer to be grown independent of substrate or substrate material.

In various embodiments of the present disclosure, the crystal layer includes a semiconductor material or a transition metal chalcogenide. In various embodiments, the crystal layer may have one or more dative bonds connecting the crystal layer to the van der Waals template.

In various embodiments of the present disclosure, the semiconductor material may be chosen from GaAs, GaN, CdTe, CdSe, ZnS, ZnSe, GaSe, GaSb, InSe, InSb, GeS, GeSe, GeTe, SnS, SnSe, PbS, PbSe, and CdSe.

In embodiments, the transition metal chalcogenide has the structure AxB_{y}, wherein A is a transition metal, B is a chalcogen, and x and y are integer numbers. In some embodiments, for example, the transition metal chalcogenide may be Cr₂Te₃, Cr₂Se₃, Cr₅Te₈, Fe₂Se₃, Fe₂S₃, Fe₃Se₄, VSe₂, Nb₂Se₃, Ta₂Se₃, ZrS₂, or HfS₂.

In some embodiments, the van der Waals template includes WSe₂ and the crystal layer includes Cr₅Te₈.

In various embodiments of the present disclosure, the substrate is sapphire, mica, MgO, or SiO₂/Si.

In various embodiments of the present disclosure, growing the van der Waals template may include heating van der Waals template precursors on the substrate.

In various embodiments, growing the crystal layer on the surface of the van der Waals template includes heating crystal layer precursors on the surface of the van der Waals template.

In various embodiments, an edge of the crystal layer is parallel to an edge of the van der Waals template. The edge of the crystal layer may, for example, be at an angle >0° relative to an edge of the van der Waals template. In some embodiments, the edge of the crystal layer is at 600 relative to the edge of the van der Waals template.

In another aspect, the present disclosure provides a Cr₅Te₈/WSe₂ heterostructure having a hybrid covalent van der Waals system of Cr₅Te₈/WSe₂, wherein the heterostructure has an interfacial structure and a plurality of the Cr atoms have dative bonds to Se atoms.

In various embodiments of the present disclosure, the heterostructure has a thickness of one unit cell to 50 μm, including every unit cell and 0.1 μm value therebetween.

In various embodiments, the Cr₅Te₈ is a crystal grown on monolayer WSe₂ and the Cr₅Te₈ crystals are self-aligned such that an edge of Cr₅Te₈ crystal is parallel to an edge of the monolayer WSe₂. In various embodiments, the Cr₅Te₈ crystals are self-aligned such that an edge of Cr₅Te₈ crystal is at an angle >0° relative to an edge of the monolayer WSe₂. In some embodiments, the Cr₅Te₈ crystals are self-aligned such that the edge of Cr₅Te₈ crystal is 60° relative to the edge of the monolayer WSe₂.

The steps of the method described in the various embodiments and examples disclosed herein are sufficient to carry out the methods of the present invention. Thus, in an embodiment, the method consists essentially of a combination of the steps of the methods disclosed herein. In another embodiment, the method consists of such steps.

The following statements provide various examples of the present disclosure.

Statement 1. A method for making a two-dimensional heterostructure comprising: i) depositing one or more van der Waals template precursors on a substrate such that a van der Waals template grows on the substrate; and, ii) depositing one or more crystal layer precursors on a surface of the van der Waals template such that a crystal layer grows on the van der Waals template, wherein the crystal layer is an epitaxial crystal layer.

Statement 2. The method of Statement 1, wherein the van der Waals template comprises having a formula of MX₂; wherein M is chosen from Ti, Hf, V, Nb, Ta, Mo, W, Re, Co, Pt, and Zr; and wherein X is chosen from S, Se, and Te.

Statement 3. The method of Statement 2, wherein the van der Waals template is chosen from WSe₂, WS₂, WTe₂, NbSe₂, MoS₂, MoSe₂, MoTe₂, and VSe₂.

Statement 4. The method of any one of Statements 1-3, wherein the crystal layer comprises a semiconductor material or a transition metal chalcogenide.

Statement 5. The method of Statement 1, wherein the crystal layer has one or more dative bonds connecting the crystal layer to the van der Waals template.

Statement 6. The method of Statement 4, wherein the semiconductor material is chosen from GaAs, GaN, CdTe, CdSe, ZnS, ZnSe, GaSe, GaSb, InSe, InSb, GeS, GeSe, GeTe, SnS, SnSe, PbS, PbSe, and CdSe.

Statement 7. The method of Statement 4, wherein the transition metal chalcogenide has the structure AxB_{y}, wherein A is a transition metal, B is a chalcogen, and x and y are integer numbers.

Statement 8. The method of Statement 7, wherein the transition metal chalcogenide is chosen from Cr₂Te₃, Cr₂Se₃, Cr₅Te₈, Fe₂Se₃, Fe₂S₃, Fe₃Se₄, VSe₂, Nb₂Se₃, Ta₂Se₃, ZrS₂, and HfS₂.

Statement 9. The method of any one of the preceding Statements, wherein the van der Waals template comprises WSe₂ and the crystal layer comprises Cr₅Te₈.

Statement 10. The method of any one of the preceding Statements, wherein the substrate is sapphire, mica, MgO, or SiO₂/Si.

Statement 11. The method of any one of the preceding Statements, wherein growing the van der Waals template comprises heating van der Waals template precursors on the substrate.

Statement 12. The method of any one of the preceding claims, wherein growing the crystal layer on the surface of the van der Waals template comprises heating crystal layer precursors on the surface of the van der Waals template.

Statement 13. The method of any one of Statements 1-12, wherein an edge of the crystal layer is parallel to an edge of the van der Waals template.

Statement 14. The method of any one of Statements 1-12, wherein an edge of the crystal layer is at an angle >0° relative to an edge of the van der Waals template.

Statement 15. The method of Statement 14, wherein the edge of the crystal layer is at 600 relative to the edge of the van der Waals template.

Statement 16. A Cr₅Te₈/WSe₂ heterostructure comprising a hybrid covalent van der Waals system of Cr₅Te₈/WSe₂, wherein the heterostructure has an interfacial structure and a plurality of the Cr atoms have dative bonds to Se atoms.

Statement 17. The Cr₅Te₈/WSe₂ heterostructure of Statement 16, wherein the heterostructure has a thickness of one unit cell to 50 μm.

Statement 18. The Cr₅Te₈/WSe₂ heterostructure of Statement 16 or Statement 17, wherein the Cr₅Te₈ is a crystal grown on monolayer WSe₂ and the Cr₅Te₈ crystals are self-aligned such that an edge of Cr₅Te₈ crystal is parallel to an edge of the monolayer WSe₂.

Statement 19. The Cr₅Te₈/WSe₂ heterostructure of Statement 12 or Statement 13, wherein the Cr₅Te₈ is a crystal grown on monolayer WSe₂ and the Cr₅Te₈ crystals are self-aligned such that an edge of Cr₅Te₈ crystal is at an angle >0° relative to an edge of the monolayer WSe₂.

Statement 20. The Cr₅Te₈/WSe₂ heterostructure of Statement 19, wherein the Cr₅Te₈ is a crystal grown on monolayer WSe₂ and the Cr₅Te₈ crystals are self-aligned such that the edge of Cr₅Te₈ crystal is 60° relative to the edge of the monolayer WSe₂.

The following examples are presented to illustrate the present disclosure. They are not intended to be limiting in any matter.

### Example 1

This example provides a description of hybrid covalent-van der Waals (vdW) system 2D heterostructures by dative epitaxy.

### Materials and Methods

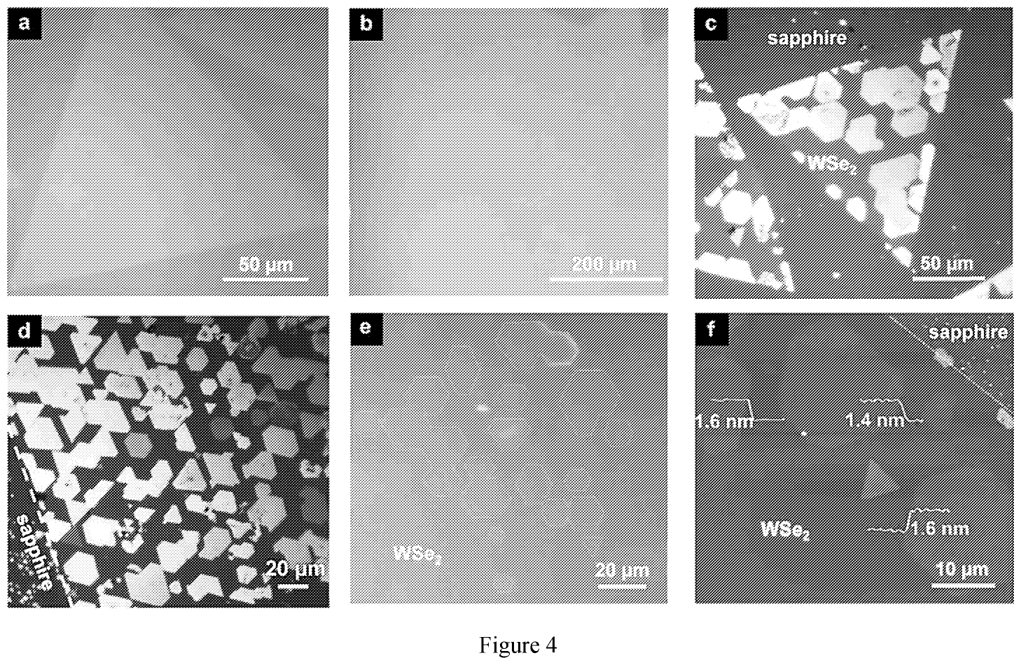

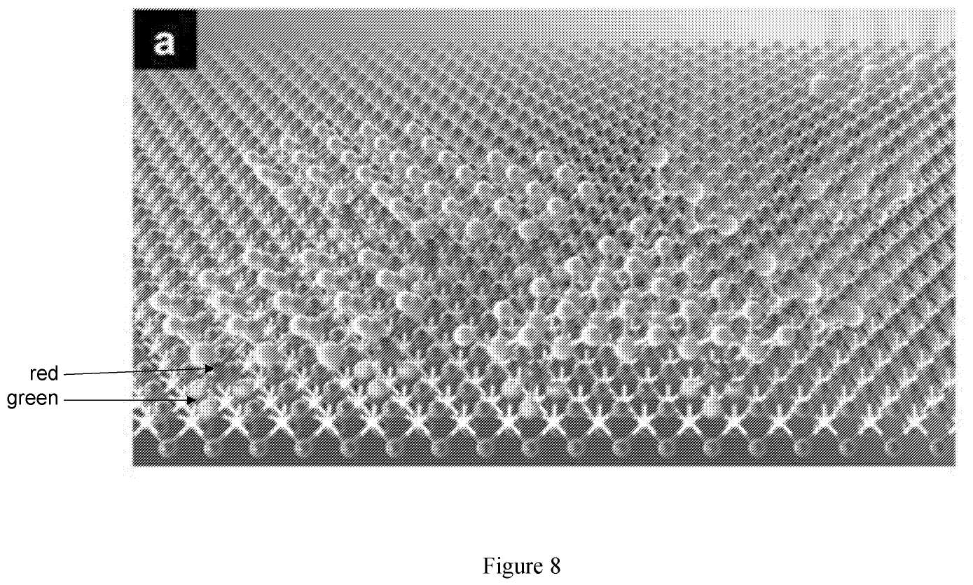

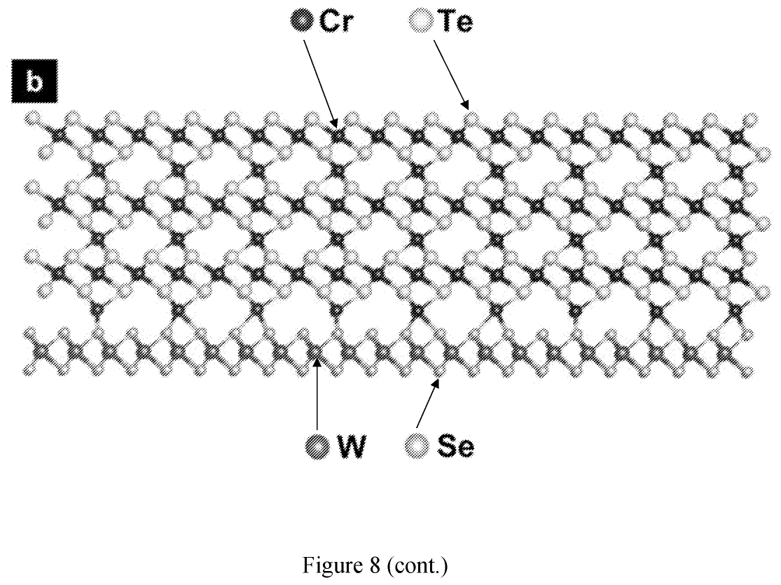

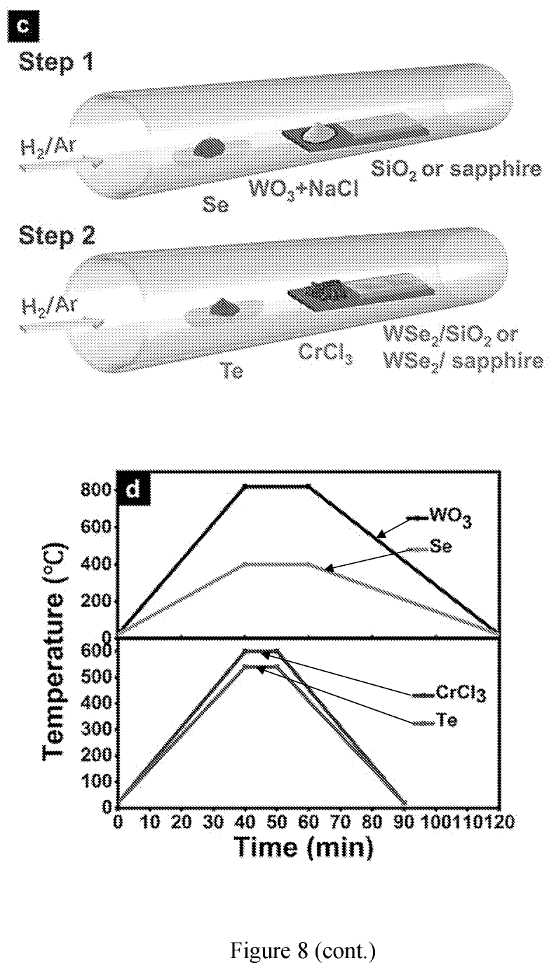

Synthesis of Cr₅Te₈/WSe₂ heterostructures: Cr₅Te₈/WSe₂ heterostructures were synthesized through a two-step CVD process in a two-zone tube furnace with a 2 inch diameter. A schematic of the experimental setup and the heating profiles of the synthesis were shown in FIG. 8c, d. In the first step, WSe₂ monolayer was grown on sapphire or SiO₂/Si substrate. In a typical synthesis, 200 mg Se powder was placed in the first heating zone upstream of the furnace, which was kept at 400° C. during the growth. 5 mg WO₃ was mixed with 0.5 mg NaCl and loaded in the second heating zone downstream. Sapphire substrates were placed close to the WO₃ powder, while SiO₂/Si substrates were placed face down directly above the WO₃ powder. The second heating zone was heated with a ramping rate of 20° C./min to the growth temperature of 820° C. and held at that temperature for 20 min before cooling down. During the growth process, the flow rate of 2% H₂/N₂ was kept at 80 standard cubic centimeters (sccm), and the growth was at ambient pressure. In the second step, the as-grown WSe₂ were used as the template for the epitaxial growth of 2D Cr₅Te₈ crystals to obtain Cr₅Te₈/WSe₂ heterostructures. 40 mg Te powder was placed in the first heating zone and ramped to 540° C. at a rate of 13° C./min, and kept at 540° C. for 10 min. 1.2 mg CrCl₃ powder was placed in the second heating zone, and heated to 600° C. at a rate of 15° C./min. The growth time was fixed at 10 min. A gas mixture containing 90% Ar and 10% H₂ with a flow rate of 100 sccm was used to carry the precursor vapor species to the substrate. Once the reaction ended, the furnace was cooled down naturally to room temperature. The schematic of the growth process of 2D Cr₅Te₈/WSe₂ moiré superlattices is shown in FIG. 8a. The CVD growth of 2D Cr₅Te₈ crystals on WSe₂ template is dictated by monomer adsorption, desorption, and surface diffusion (as seen in FIG. 8a). The weak bonding between the monomer and the WSe₂ vdW template leads to low barriers for surface diffusion. For Cr₅Te₈, the intralayer covalent bonding is substantially stronger than the interlayer bonding due to the presence of ordered vacancies. Such bonding character results in stronger adsorption energy of the monomers at the edges than that on the top surfaces. Together with ease of diffusion of monomers on the surface of WSe₂, atomically thin Cr₅Te₈ crystals can be achieved. The Cr₅Te₈/WSe₂ heterostructures with relatively thick (˜10 nm) and thin (1.4 to 2.8 nm) Cr₅Te₈ crystals were achieved by controlling the distance between the CrCl₃ precursor and the substrate, with ˜0.2 mm for the samples shown in FIG. 4d and ˜2 mm for the ones in FIG. 4e. Due to the high melting point (1,150° C.) of CrCl₃, a steep vapor concentration gradient was established at the growth temperature of 600° C. At a large precursor-substrate distance, the vapor concentration can be kept below the threshold of new nucleation on top of existing 2D layers, resulting in atomically thin Cr₅Te₈ crystals. Interestingly, the 2D Cr₅Te₈ crystals deposit highly selectively on WSe₂ only, leaving sporadic nanocrystals on sapphire, as seen in FIG. 4c. Without intending to be bound to any specific theory, it is thought that the absence of 2D crystal growth on these substrates is attributable to the covalent bonding and thus large surface diffusion barrier for monomers. This leads to 3D growth of nanoparticles which eventually dewet due to surface tension.

Film transfer: The as-grown Cr₅Te₈/WSe₂ heterostructures were transferred onto TEM grids by dry transfer in a glovebox with a nitrogen atmosphere. The Cr₅Te₈/WSe₂ heterostructures on SiO₂/Si substrate were first covered by polymethylmethacrylate (PMMA). After baking at 80° C. for 5 min, the PMMA film with Cr₅Te₈/WSe₂ heterostructures was peeled off the SiO₂/Si substrate and then transferred to a TEM grid in a home-built alignment stage integrated with an optical microscope, followed by 5 min baking at 80° C. The PMMA was removed by immersing the sample in acetone for 30 min.

Cross-sectional STEM sample preparation: The as-grown Cr₅Te₈/WSe₂ heterostructure was exposed to a nitrogen atmosphere and subsequently covered by graphite through a routine dry-transfer method in the glovebox to protect the surface from being oxidized. The cross-section STEM sample was prepared by using Focused Ion Beam (FIB) milling. It was thinned down to 70 nm thick at an accelerating voltage of 30 kV with a decreasing current from 0.79 nA to 80 pA, followed by a fine polish at an accelerating voltage of 2 kV with a small current of 21 pA to remove the amorphous layer.

HAADF-STEM characterization: The atomically resolved HAADF-STEM images were carried out on an aberration-corrected scanning transmission electron microscope (FEI Tian Themis 60-300 kV, operated at 300 kV). This TEM is equipped with a DCOR aberration corrector and a high-brightness field emission gun (X-FEG) with monochromator. The inner and outer collection angles for the STEM images (β1 and β2) were 38 and 200 mrad, respectively, with a semi convergence angle of 30 mrad.

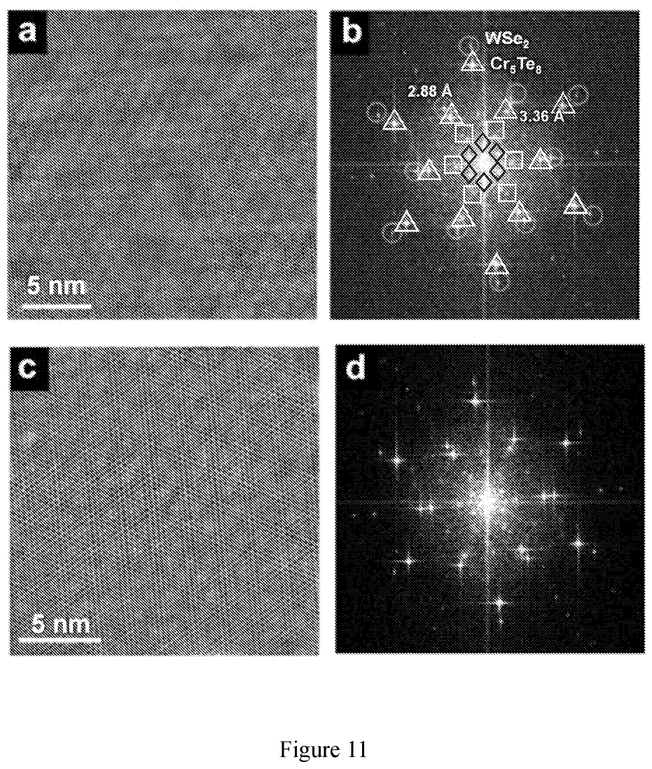

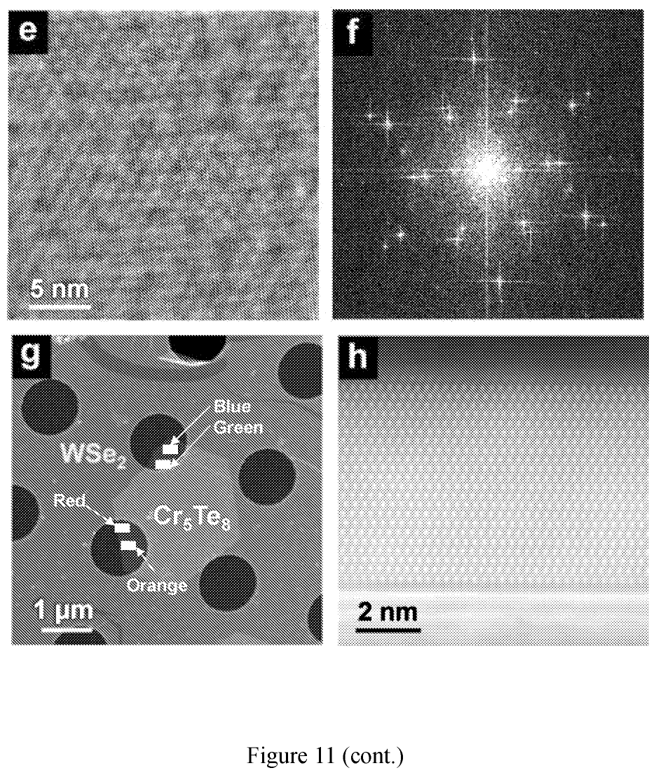

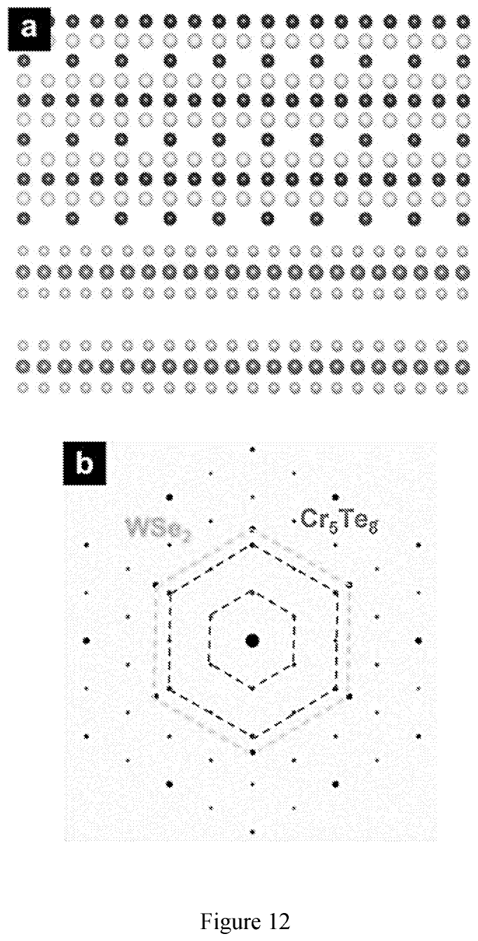

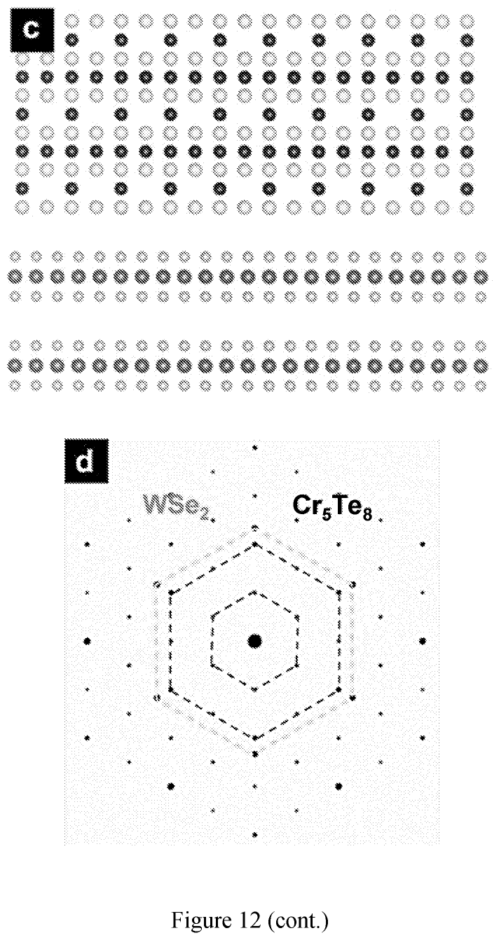

Cross-sectional STEM imaging: The cross-sectional HAADF-STEM reveals a clear vdW-like gap between the Cr₅Te₈ and WSe₂ layers as shown in FIG. 11h, but Cr sites are nearly invisible due to strong scattering of Te which has a much larger atomic weight. To reveal the position of Cr, we adopted integrated differential-phase contrast (iDPC) imaging, which measures the projected electrostatic potential instead of the integrated scattering signal of the atomic column.

STEM-EELS characterization: EELS were acquired in the STEM mode and collected by setting the energy resolution to 1 eV at full width at half maximum (FWHM) of the zero-loss peak. The dispersion used is 0.5 eV/channel. EELS are acquired in the dual EELS mode to eliminate any systematic error due to the drift of the zero-loss peak.

Raman and photoluminescence spectra were measured using a confocal Renishaw inVia Raman microscope equipped with a 514 nm laser. A 50× objective lens was used to focus the excitation lasers onto the sample and collect the emitted signals.

DFT-based ab-initio calculations were performed by using the Vienna ab initio Simulation Package (VASP) package. The Perdew-Burke-Ernzerhof (PBE) form of the exchange correlation functional was used. Slab calculations were performed using supercell approach with a vacuum layer of ˜15 Å (to remove interaction between periodically repeated layers). The supercell was constructed using the observed moiré superlattice. The in-plane lattice constant of Moiré superlattice was set at 23.3 Å. Plane-wave cut-off energy of 400 eV, and 4×4=1 Monkhorst-Pack k-point mesh. The atomic positions were optimized by the conjugate gradient method to have all forces less than 10-2 eV/A. Spin-orbit was added after the relaxation accuracy was achieved. Zero damping DFT-D3 method of Grimme models Van der Waals interactions.

RMCD measurements: The samples for RMCD measurements were capped with 2 nm Al by sputter deposition to prevent oxidization. The RMCD is defined as (σ₊−I_{σ-})/(I_{σ+}−I_{σ-}), where the I_{σ±} are the intensities of the reflected right and left circularly polarized light. RMCD measurements were performed with the sample mounted on a custom microscope/nano positioner probe that was loaded into the variable-temperature helium insert of a 7 T magneto-optical cryostat (Oxford Instruments Spectramag). Light from a 633 nm HeNe laser was linearly polarized, and then modulated between left- and right-circular polarization at 50 kHz using a photoelastic modulator, before being focused to a 1-micron diameter spot on the sample. Light reflected from the sample was detected by an avalanche photodiode, and the normalized difference between the two polarizations was measured using a lock-in amplifier.

### Example 2

This example provides a description of hybrid covalent-van der Waals (vdW) system 2D heterostructures by dative epitaxy.

A large-scale WSe₂ monolayer millimeter in size was first grown on a sapphire or Si/SiO₂ substrate by CVD. Atomically thin Cr₅Te₈, a non-vdW ferromagnet that can be considered as Cr atoms self-intercalated between the CrTe₂ layers (as shown schematically in FIG. 8b), was then epitaxially grown with WSe₂ as the vdW template. The weak interaction between the atomically flat, dangling bond-free WSe₂ and precursor molecules lowers the surface diffusion barrier for the growth of 2D Cr₅Te₈ crystals with thicknesses down to a single unit cell and sizes of tens of microns. Meanwhile, the interfacial Cr atoms serve as the anchoring atoms to fix the atomic registry and orientation of 2D Cr₅Te₈, by forming dative bonds, special covalent bonds where the bonding electrons derive from the same atom, with Se atoms in WSe₂. As a result, a globally commensurate, monocrystalline 3×3/7×7 Cr₅Te₈/WSe₂ moiré supercrystal with a well-defined interfacial structure is achieved, which differs from conventional moiré superlattices with spatially varying rigid moiré patterns or local commensurate domain reconstruction.

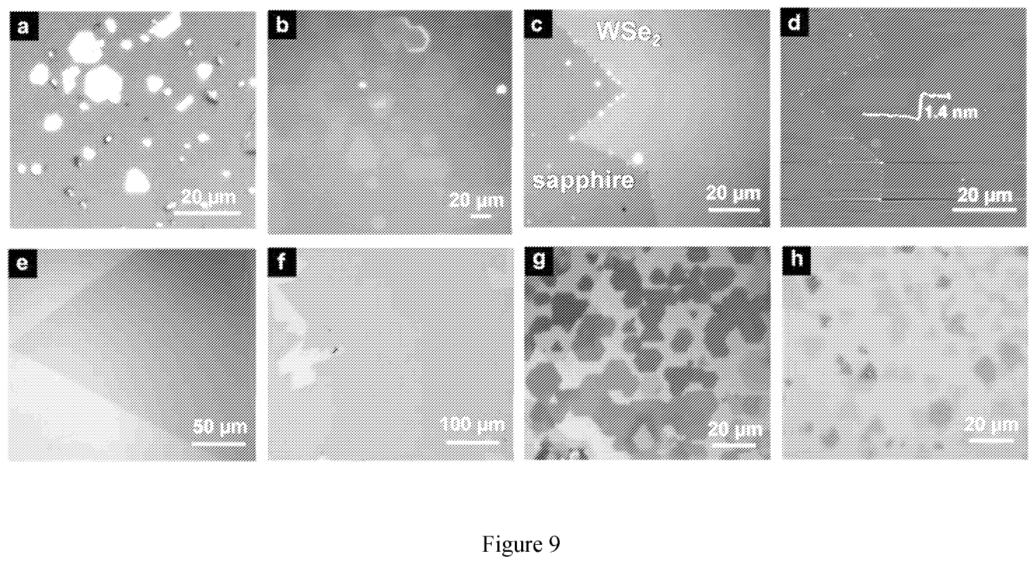

CVD grown monolayer WSe₂ with lateral dimensions of 100-2,000 μm, used as templates for the growth of Cr₅Te₈/WSe₂ heterostructures, are shown in FIG. 4a, b. A typical optical microscope image of the heterostructures is shown in FIG. 4c. Strikingly, all the Cr₅Te₈ crystals grown on a single monolayer WSe₂ are self-aligned, with one of their edges oriented either parallel or at a 600 angle to one of the edges of WSe₂, in contrast to the randomly oriented Cr₅Te₈ crystals grown directly on sapphire (FIG. 9a). This strongly suggests that the Cr₅Te₈ crystals grow epitaxially on WSe₂.

While monolayer WSe₂ is randomly oriented, the orientations of the Cr₅Te₈ crystals align with individual WSe₂ crystals, suggesting the dominant role of monolayer WSe₂ in the epitaxial growth. Therefore, such vdW templates also allow the synthesis of highly oriented 2D Cr₅Te₈ crystals independent of substrates, as evidenced by samples grown on amorphous SiO₂ substrates (FIG. 9g, h).

Optical microscope images of Cr₅Te₈/WSe₂ heterostructures with relatively thick (˜10 nm) and thin (1.4 to 2.8 nm) Cr₅Te₈ crystals are shown in FIGS. 4d and 4e, respectively. They were achieved by controlling the distance between the CrCl₃ precursor and the substrate. The atomically thin Cr₅Te₈ crystals in FIG. 4e exhibit extremely weak contrast. To help discern these crystals from the substrate, the boundaries of these crystals are highlighted by the dashed lines (the same image with enhanced contrast is shown in FIG. 9b). A group of one unit cell thick, aligned Cr₅Te₈ crystals on WSe₂ are further shown by the atomic force microscopy (AFM) image in FIG. 4f and FIG. 9d.

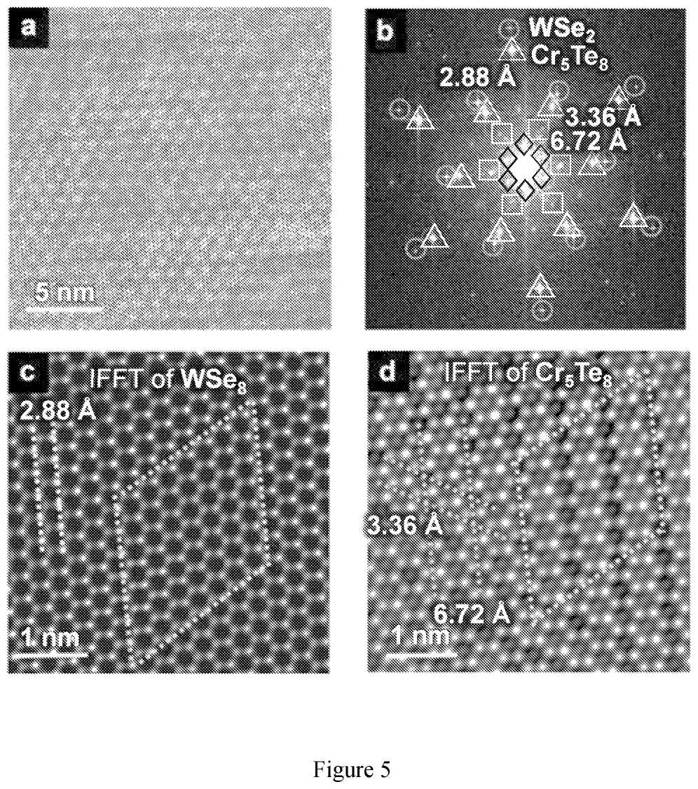

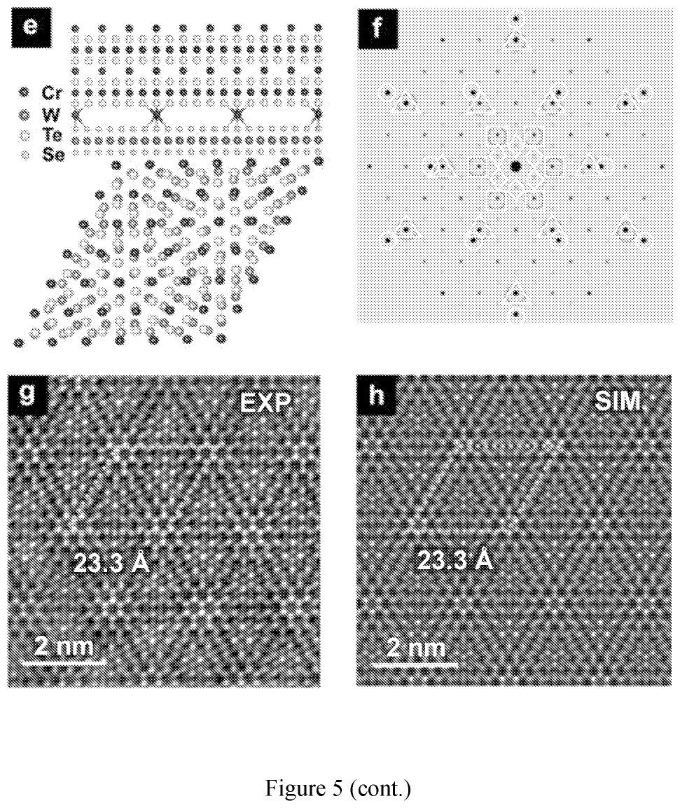

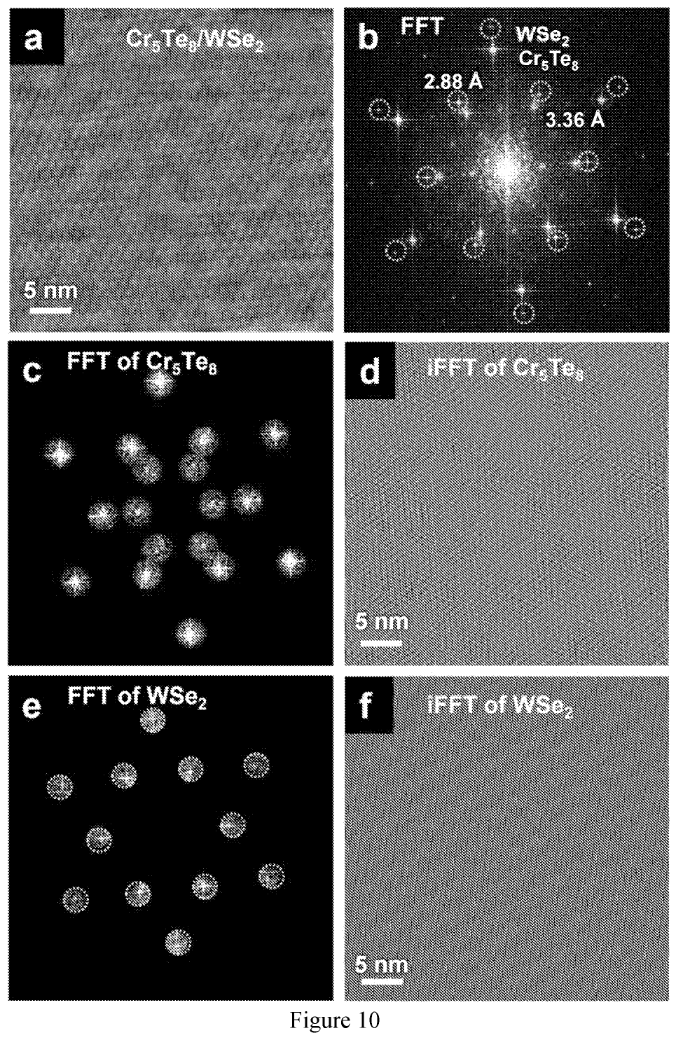

The a lattice constants of WSe₂ and Cr₅Te₈ are 3.33 and 7.90 Å, respectively. With ˜16% lattice mismatch, defined as (a_{Cr}_{₅}_{Te}_{₈}−2*a_{WSe}_{₂})/a_{Cr}_{₅}_{Te}_{₈}, any epitaxial growth of the Cr₅Te₈/WSe₂ hetero structure would imply the formation of moiré superlattices. Indeed, a moiré pattern can be clearly seen in the atomically resolved plane-view high angle annular dark field scanning transmission electron microscopy (HAADF-STEM) image in FIG. 5a. The fast Fourier transform (FFT) pattern (FIG. 5b) reveals three distinct sets of diffraction spots with six-fold symmetry, marked by yellow, red, and blue circles, respectively. The lattice spacing of the diffraction spots marked by yellow circles is 2.88 Å, which is consistent with the measured (100) lattice spacing of monolayer WSe₂. The diffraction spots marked with red circles show identical orientation with that of the WSe₂, with a lattice spacing of 3.36 Å in accordance with the Cr₅Te₈ (200) planes, which implies a ˜2% reduction from the value of individual Cr₅Te. The inner, red-circled diffraction spots with a larger periodicity (6.72 Å) representing those ordered, self-intercalated Cr atoms is a structural fingerprint of trigonal Cr₅Te₈. Interestingly, the innermost diffraction spots highlighted by blue circles indicate a lattice spacing of 11.5 Å, which belongs to neither WSe₂ nor Cr₅Te₈ alone, suggesting that it may originate from the periodicity of the moiré superlattice of the Cr₅Te₈/WSe₂ heterostructure. The individual lattices of Cr₅Te₈ and WSe₂ are resolved by inverse FFT (iFFT) of the corresponding filtered diffraction spots (FIG. 10), showing hexagonal lattices of both WSe₂ and Cr₅Te₈ aligned in identical orientation, as seen in FIGS. 5c and 5d, respectively. An atomic model of the Cr₅Te₈/WSe₂ heterostructure based on iterative refinements from HAADF-STEM image analysis and first principles calculations is shown in FIG. 5e, where a 3×3 Cr₅Te₈ supercell is commensurate with the 7×7 WSe₂ supercell. To generate the larger periodicity with six-fold symmetry that reproduces the observed moiré diffraction pattern shown by the blue circles in FIG. 5b, the model requires the number of interfacial Cr atoms to be reduced to 3 per supercell from 9 self-intercalated in the interior of Cr₅Te₈, suggesting interfacial reconstruction. In slight variations of the atomic model, either without interfacial Cr or with 9 interfacial Cr per supercell, the moiré superlattice diffraction pattern is noticeably missing since it is symmetry forbidden. This further confirms the reconstructed interface with suitable Cr occupation is a necessary condition for the observed moiré diffraction pattern and the commensurate moiré superlattice. As can be seen from FIG. 5f, the simulated diffraction pattern matches well with that of FIG. 5b. The high-resolution STEM image reveals the perfectly commensurate moiré superlattice with a lattice constant of 23.3 Å, as shown in FIG. 5g. The simulated STEM image (FIG. 5h) based on the atomic model reproduces the moiré pattern observed.

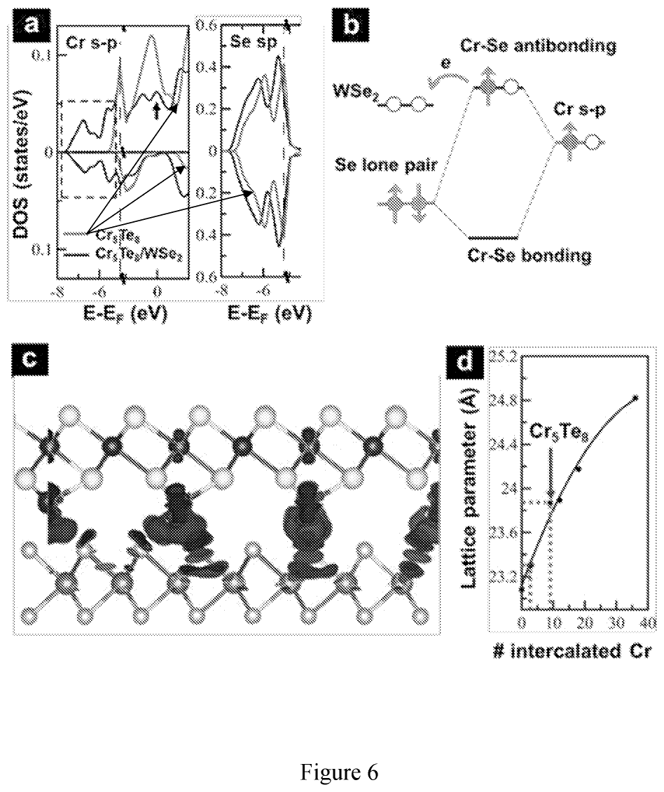

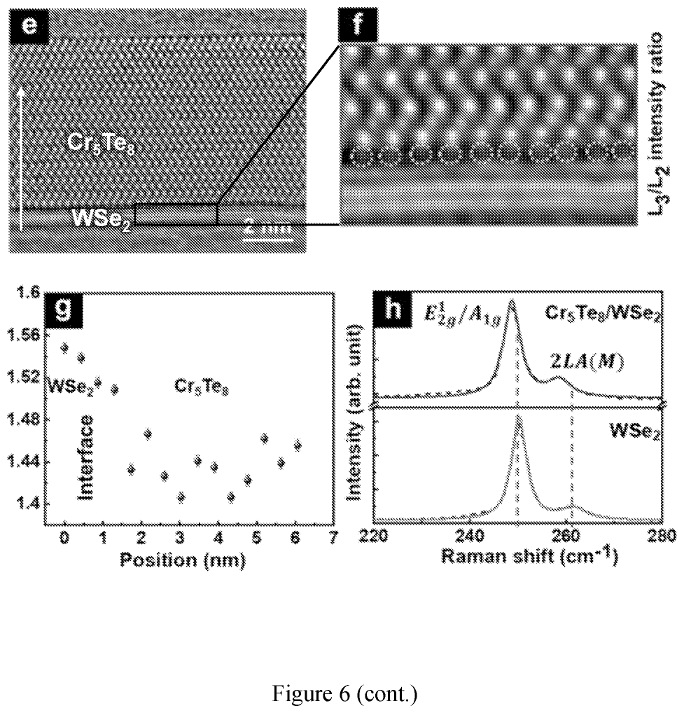

First principles calculations were carried out to understand the atomic structure, charge transfer, and chemical bonding at Cr₅Te₈/WSe₂ interface. In bulk, the self-intercalated Cr atoms are coordinated with 6 Te atoms arranged on the corners of a triangular prism, as seen in FIG. 5e. At the interface, not only the density of the intercalated Cr atoms is reduced, but the crystal symmetry is also lowered, as these Cr atoms coordinate to Se on the WSe₂ side, forming a Te—Cr—Se Janus interface. FIG. 6a compares the site-decomposed partial DOSs of interfacial Cr (left panel) and Se (right panel) sp states for isolated Cr₅Te₈ and WSe₂ monolayer (red curves) with those of WSe₂/Cr₅Te₈ heterostructure (black curves). As can be seen from the change of DOS of Cr in the left panel, the majority spin state peak near the Fermi level (the red peak) is suppressed. Accompanying the suppression, a band at ˜−7 to −4 eV (shown in the box) emerges. The emergence of this low-lying Cr band is a result of hybridization with the Se sp states, whose energy is also lowered due to the hybridization, as can be seen in the right panel.

One can understand the above results based on a level repulsion picture in FIG. 6b: the two states shown in red color are the interfacial Cr and Se sp states before Cr₅Te₈ and WSe₂ form the heterostructure. When forming the heterostructure, the Cr and Se sp states hybridize; the high-lying Cr sp state is pushed up in energy forming an anti-bonding state so its spectra weight near the Fermi level is suppressed, while the low-lying Se sp state is pushed down forming a bonding state in line with the result in the right panel in FIG. 6a. As this is a hybridization, Cr also takes a significant share in the newly-formed low-lying state, as evidenced by the band at ˜−7 to −4 eV in the left panel in FIG. 6a. Interestingly, after the hybridization, the antibonding state lies about the WSe₂ conduction band edge, resulting in a charge transfer from the interfacial Cr to WSe₂ conduction band with an energy reduction. FIG. 6c shows the differential (deformation) charge density Δp, which reveals a bonding-state charge accumulation in-between the interfacial Cr and Se atoms. Based on the Bader analysis (see Table 1), the total amount of charge accumulated is about 1 electron per supercell. The interfacial Cr—Se bond length of 2.88 Å is noticeably longer than the 2.56 Å for Cr₂Se₃. The interfacial binding energy of ˜1 eV/Cr is an order of magnitude larger than a typical vdW binding, but is only half of the usual Cr—Se covalent bond. These results point consistently to the formation of dative bonds at the interface, which originates from a Coulomb attraction between anion lone pairs (i.e., the fully occupied surface Se dangling bond states) and the empty orbitals of the metal cations (i.e., the nearly empty Cr sp states upon electron transfer to the WSe₂ conduction band) and is intermediate in energy between the vdW binding and covalent bond. The formation of the dative bonds weakens adjacent Cr—Te and W—Se bonds, e.g., the W—Se bond length increases from 2.545 to 2.550 Å.

TABLE 3
Bader charges calculated for Cr₅Te₈/WSe₂ moiré superlattice
compared to those of the individual Cr₅Te₈ and WSe₂ layer (the unit is e).

| | | | | | Cr₅Te₈ | WSe₂ |
|---|---|---|---|---|---|---|
| | Cr/Cr(int) | Te | W | Se | layer | layer |
| Cr₅Te₈/WSe₂ | 5.26375/5.2476 | 6.44836 | 5.1464 | 6.4596/6.4143 | 701.0056 | 882.9943 |
| Cr₅Te₈ | 5.26375/5.32335 | 6.45271 | 5.1410 | | 702 | |
| WSe₂ | | | | 6.429 | | 882 |
| Charge | 0/−0.07574 | −0.0044 | 0.0054 | 0.0306/−0.0147 | −0.9943 | 0.9943 |
| transfer | | | | | | |

In the fifth column, the first number is for the Se atoms at the interface, and the second number is for the atoms at the free surface. The Bader charge analysis shows that there is a charge transfer from Cr₅Te₈ towards WSe₂. There is ~1e transferred across the interface. The largest charge transfer occurs for the intercalating Cr atom. It donates electrons to form a dative bond with Se in WSe₂. Some charge is also transferred to W, although significantly smaller. Due to the asymmetry of the charge between Se sites at the interface and free surface, there is a polarity in charge distribution across the WSe₂ monolayer.

The formation of directional dative bonds is ultimately responsible for fixing the atomic registry and orientation of the Cr₅Te₈ 2D crystals on WSe₂ monolayer. It represents a new regime of thin film epitaxy that is distinctly different from either a conventional 3D epitaxy with strong covalent bond or a standard vdW epitaxy. Dative epitaxy can be generally applicable to other covalent materials on vdW templates. FIG. 6d plots the calculated bulk lattice parameters of CrTeₓ (represented by the superlattice parameter) as a function of the number of self-intercalated Cr atoms. It can be seen that the lattice parameter shrinks monotonically with decreasing the number of Cr atoms, e.g. from 23.8 Å for 9 Cr in Cr₅Te₈ to 23.3 Å for 3 Cr. Note 3 Cr is identical to the interfacial Cr number in the atomic model that reproduces the moiré diffraction pattern, and 23.3 Å is the measured moiré superlattice parameter that is exactly 7 times the lattice constant of monolayer WSe₂. Without intending to be bound to any specific theory, it is thought that dative bond formation is inherently optimized to remove the ˜2% interfacial strain that would appear otherwise for the epitaxial growth.

In conventional vdW heterostructures with large lattice mismatch, either in commensurate superlattices with spatially varying moiré patterns or local commensurate domain reconstruction were observed. For the Cr₅Te₈/WSe₂ system, however, the atomic structure is optimized with the right number of dative bonds at the interface. This would allow nearly strain-free commensurate moiré superlattices over the entire 2D heterostructure. As evidenced by the HAADF-STEM images taken at different spots of a single Cr₅Te₈/WSe₂ heterostructure (FIG. 11), identical, perfectly commensurate moiré patterns were observed across the heterostructure, suggesting that the Cr₅Te₈/WSe₂ is a monocrystalline moiré supercrystal. Such a monocrystalline moiré supercrystal has not been reported before and provides strong evidence for the proposed dative epitaxy mechanism.

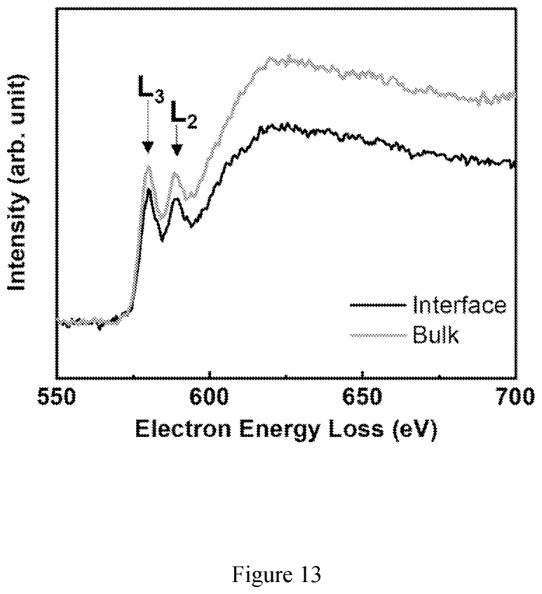

The cross-section of a relatively thick (˜7 nm) Cr₅Te₈ layer grown on WSe₂ were imaged by HAADF-STEM to reveal atomic details of the interface (atomically thin Cr₅Te₈/WSe₂ was oxidized during cross-sectional sample preparation). To reveal the position of Cr atoms that are much lighter than Te, integrated differential-phase contrast (iDPC) imaging technique were employed. As can be seen in FIG. 6e, the cross-section of Cr₅Te₈ viewed along (100) direction matches well with the atomic model in FIG. 8b. Atomic columns with substantially weaker contrast inside the vdW-like gap can be seen from the zoomed-in view in FIG. 6f, which is attributed to the reduced number of interfacial Cr atoms, consistent with the atomic model matching diffraction and theoretical predictions. The local valence states of Cr atoms across the interface were mapped using the integrated intensity ratio of the electron energy loss spectroscopy (EELS) L₃ and L₂ excitation peaks (the so-called “white line ratio”). As shown in FIG. 6h, the Cr L₃/L₂ ratio increases towards the interface and becomes substantially larger than the value in the Cr₅Te₈ interior, indicating a lower Cr valence state near the interface (individual EELS spectrum at the bulk and interface is provided in FIG. 13). This is because after dative bond formation and electron donation, these interfacial Cr atoms still possess excessive charge due to lower coordination.

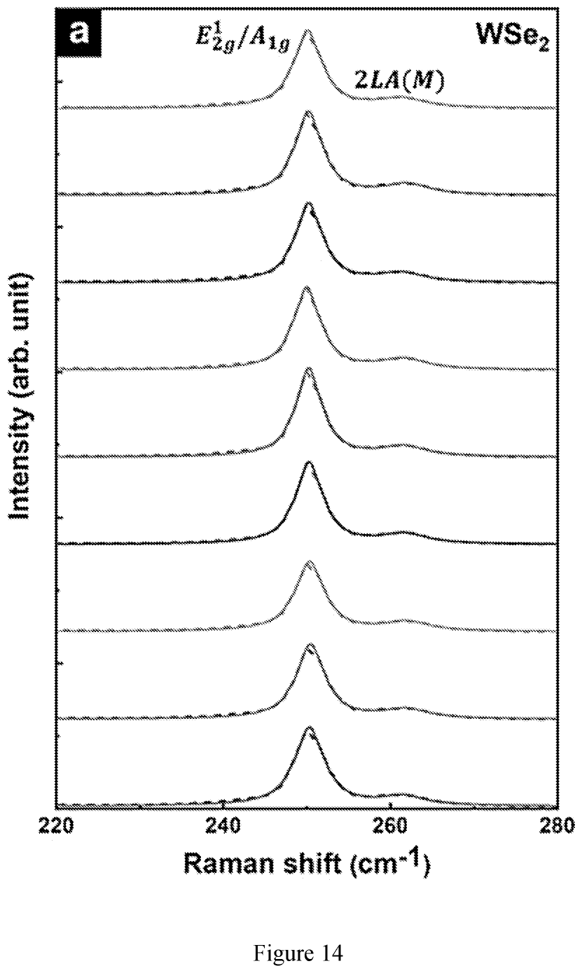

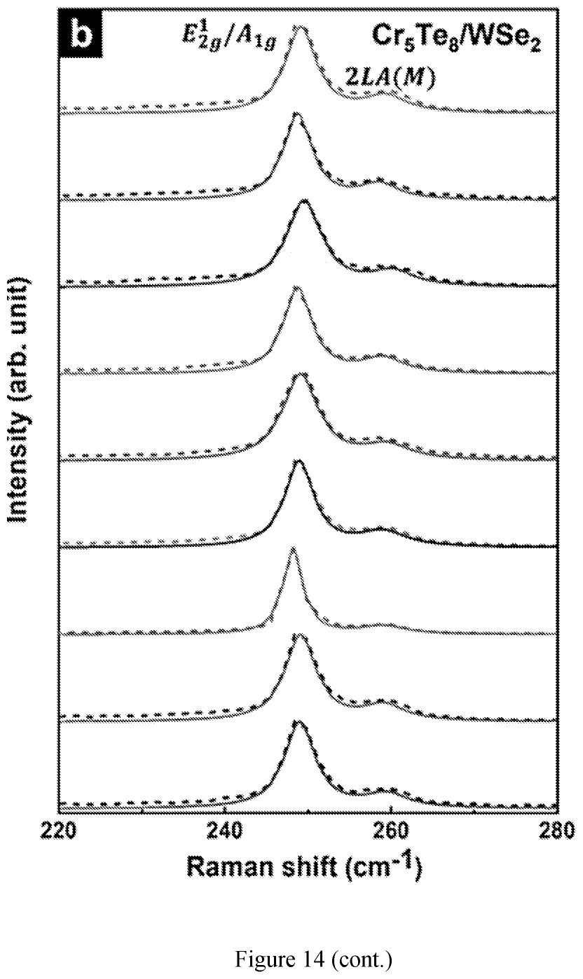

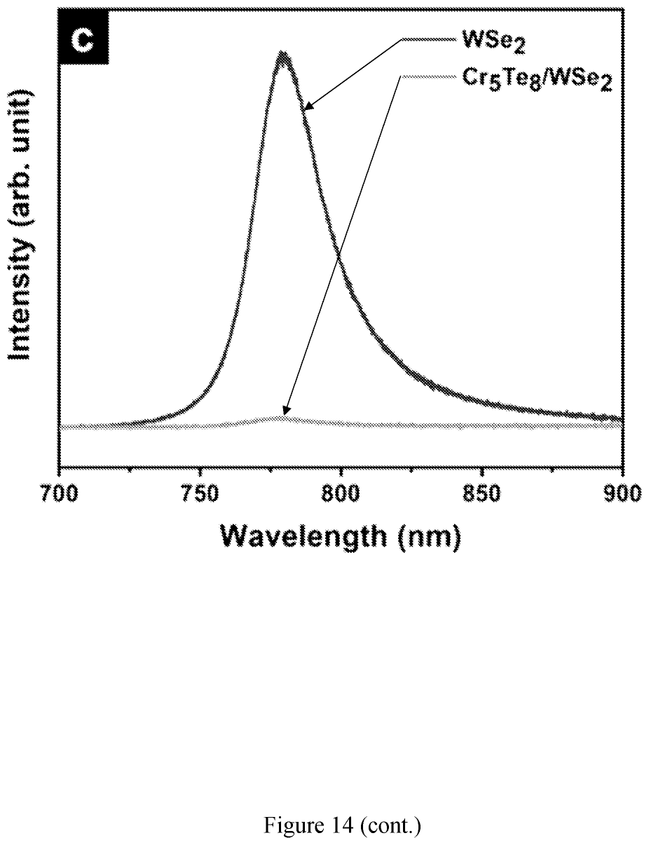

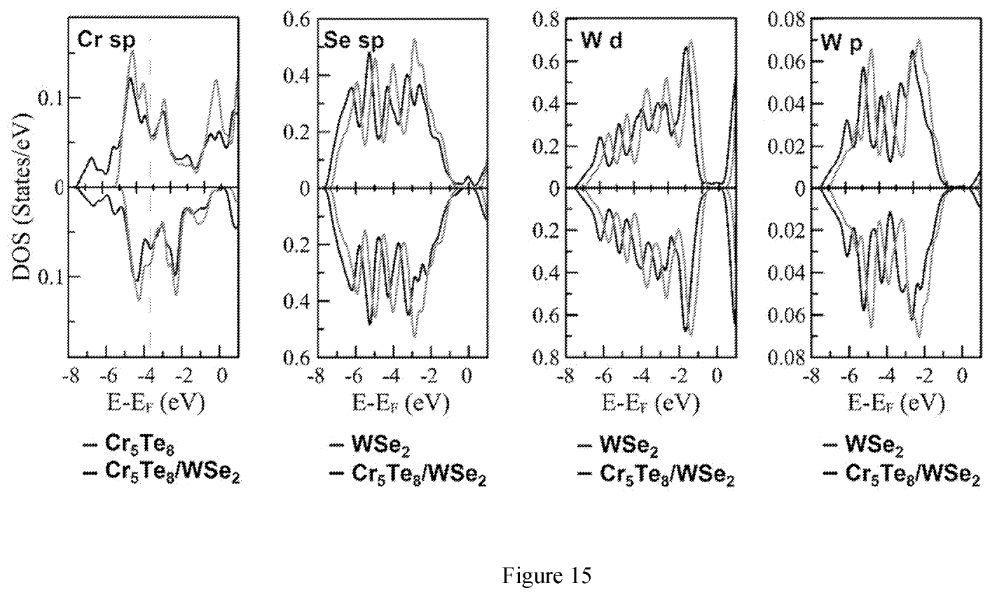

The predicted weakening of W—Se bonds in WSe₂ was further investigated by Raman spectroscopy. As seen from the bottom panel in FIG. 6h, a strong peak at ˜250 cm⁻¹ and a weak shoulder at ˜260 cm⁻¹ are observed for monolayer WSe₂, which can be attributed to the degenerate out-of-plane A_{1g} and in-plane E¹ phonon modes of WSe₂, and a second-order Raman mode due to LA phonons at the M point in the Brillouin zone labeled as 2LA(M), respectively. These modes are also observed for the Cr₅Te₈/WSe₂ moiré superlattice. However, both peaks showed a small but measurable red shift. The average Raman peak positions measured at 9 different spots each for WSe₂ and Cr₅Te₈/WSe₂ are shown in Table 1 (all spectra and fittings are shown in FIG. 14a, b and Table 2). A red shift (Δv) of 1.3 cm⁻¹ for the E¹/A mode and 2.4 cm⁻¹ for the 2LA(M) mode were observed, confirming the predicted W—Se bond softening due to dative bond formation.

TABLE 1
Raman peak positions of monolayer WSe₂ and Cr₅Te₈/WSe₂

| | Cr₅Te₈/ | | | Cr₅Te₈/ | |
|---|---|---|---|---|---|
| WSe₂ | WSe₂ | Δν | WSe₂ | WSe₂ | Δν |
| E_{2g}¹/A_{1g} | E_{2g}¹/A_{1g} | E_{2g}¹/A_{1g} | 2LA (M) | 2 LA (M) | 2 LA (M) |
| (cm⁻¹) | (cm⁻¹) | (cm⁻¹) | (cm⁻¹) | (cm⁻¹) | (cm⁻¹) |
| 250.21 ± | 248.93 ± | 1.3 | 261.63 ± | 259.24 ± | 2.4 |
| 0.04 | 0.12 | | 0.08 | 0.18 | |

TABLE 2
The representative Raman peak position of monolayer
WSe₂ and Cr₅Te₈/WSe₂ heterostructure

| WSe₂ | WSe₂ | Cr₅Te₈/WSe₂ | Cr₅Te₈/WSe₂ |
|---|---|---|---|
| E_{2g}¹/A_{1g} | 2 LA (M) | E_{2g}¹/A_{1g} | 2 LA (M) |
| (cm⁻¹) | (cm⁻¹) | (cm⁻¹) | (cm⁻¹) |
| 250.28 | 261.47 | 248.99 | 259.44 |
| 250.42 | 261.85 | 249.10 | 259.15 |
| 250.31 | 261.97 | 248.18 | 259.01 |
| 250.25 | 261.66 | 248.93 | 259.03 |
| 250.21 | 261.54 | 249.07 | 259.46 |
| 249.98 | 261.58 | 248.73 | 259.00 |
| 250.21 | 261.30 | 249.52 | 260.16 |
| 250.17 | 261.96 | 248.74 | 258.58 |
| 250.08 | 261.33 | 249.13 | 259.33 |

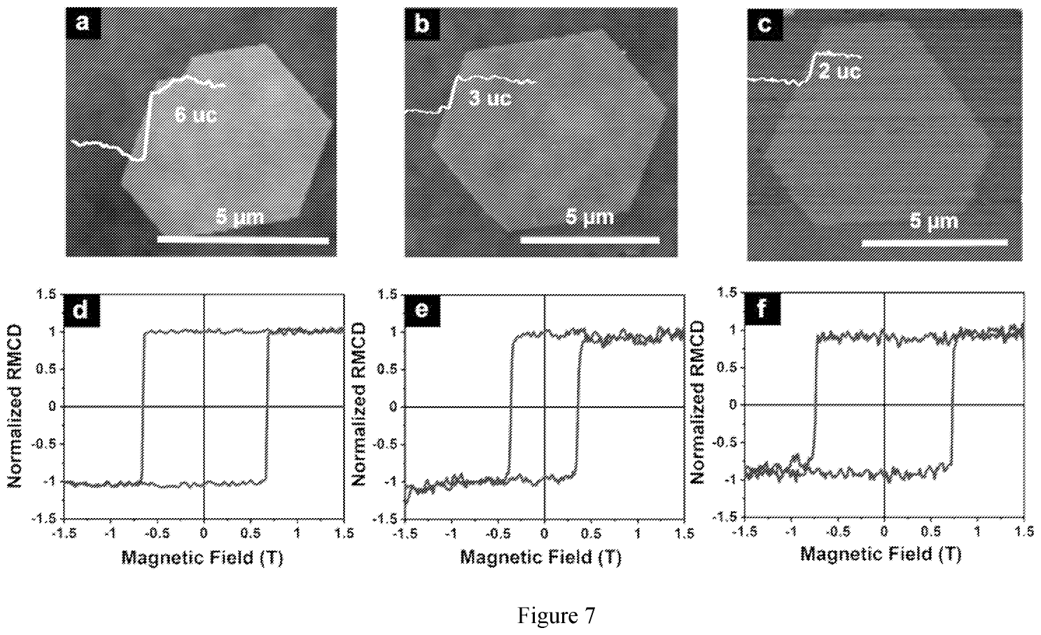

Dative epitaxy enables nearly strain-free epitaxial growth of monocrystalline Cr₅Te₈ on WSe₂, which should lead to extremely low density of interfacial defects. The out-of-plane magnetic hysteresis of single 2D Cr₅Te₈ crystals were measured by reflective magnetic circular dichroism (RMCD), which is used to infer the crystallinity of Cr₅Te₈. Shown in FIG. 7a-c are three representative 2D Cr₅Te₈ crystals with thicknesses of 8.4 nm (6 unit cells), 4.5 nm (3 unit cells) and 2.6 nm (2 unit cells), respectively. The magnetic hysteresis loops for the three crystals measured at 5 K are shown in FIG. 7d-f All three samples exhibit square hysteresis loops, with sharp transitions at the coercive fields (Hc), and unity remanence at zero field. Hc are 0.66, 0.36, and 0.74 T for 6, 3, and 2 unit cell thick crystals, respectively, which are noticeably smaller than the expected anisotropy field, suggesting that the magnetization reversal proceeds by nucleation (e.g. at a sharp corner) followed by domain wall motion. The nearly perfect square hysteresis suggests nearly absence of domain wall pinning by defects, and thus once a magnetic domain is nucleated, the domain wall can propagate freely. On the other hand, the reported magnetic hysteresis of Cr_{1.5}Te₂ nanoplates on Si/SiO₂ substrates show skewed loops with a broad switching field distribution. This suggests the presence of many defect pinning sites. This comparison suggests that 2D Cr₅Te₈ crystals obtained by dative epitaxy possess superior crystal quality and magnetic properties. For one unit cell thick Cr₅Te₈ crystals, however, no RMCD signal can be detected. The lack of magnetic signal may be due to surface oxidation.

Although the present disclosure has been described with respect to one or more particular embodiments and/or examples, it will be understood that other embodiments and/or examples of the present disclosure may be made without departing from the scope of the present disclosure.

1. A method for making a two-dimensional heterostructure comprising:
depositing one or more van der Waals template precursors on a substrate such that a van der Waals template grows on the substrate;
depositing one or more crystal layer precursors on a surface of the van der Waals template such that a crystal layer grows on the van der Waals template, wherein the crystal layer is an epitaxial crystal layer.

2. The method of claim 1, wherein the van der Waals template comprises having a formula of MX₂; wherein M is chosen from Ti, Hf, V, Nb, Ta, Mo, W, Re, Co, Pt, and Zr; and wherein X is chosen from S, Se, and Te.

3. The method of claim 2, wherein the van der Waals template is chosen from WSe₂, WS₂, WTe₂, NbSe₂, MoS₂, MoSe₂, MoTe₂, and VSe₂.

4. The method of claim 1, wherein the crystal layer comprises a semiconductor material or a transition metal chalcogenide.

5. The method of claim 1, wherein the crystal layer has one or more dative bonds connecting the crystal layer to the van der Waals template.

6. The method of claim 4, wherein the semiconductor material is chosen from GaAs, GaN, CdTe, CdSe, ZnS, ZnSe, GaSe, GaSb, InSe, InSb, GeS, GeSe, GeTe, SnS, SnSe, PbS, PbSe, and CdSe.

7. The method of claim 4, wherein the transition metal chalcogenide has the structure AxB_{y}, wherein A is a transition metal, B is a chalcogen, and x and y are integer numbers.

8. The method of claim 7, wherein the transition metal chalcogenide is chosen from Cr₂Te₃, Cr₂Se₃, Cr₅Te₈, Fe₂Se₃, Fe₂S₃, Fe₃Se₄, VSe₂, Nb₂Se₃, Ta₂Se₃, ZrS₂, and HfS₂.

9. The method of claim 1, wherein the van der Waals template comprises WSe₂ and the crystal layer comprises Cr₅Te₈.

10. The method of claim 1, wherein the substrate is sapphire, mica, MgO, or SiO₂/Si.

11. The method of claim 1, wherein growing the van der Waals template comprises heating van der Waals template precursors on the substrate.

12. The method of claim 1, wherein growing the crystal layer on the surface of the van der Waals template comprises heating crystal layer precursors on the surface of the van der Waals template.

13. The method of claim 1, wherein an edge of the crystal layer is parallel to an edge of the van der Waals template.

14. The method of claim 1, wherein an edge of the crystal layer is at an angle >0° relative to an edge of the van der Waals template.

15. The method of claim 14, wherein the edge of the crystal layer is at 60° relative to the edge of the van der Waals template.

16. A Cr₅Te₈/WSe₂ heterostructure comprising a hybrid covalent van der Waals system of Cr₅Te₈/WSe₂, wherein the heterostructure has an interfacial structure and a plurality of the Cr atoms have dative bonds to Se atoms.

17. The Cr₅Te₈/WSe₂ heterostructure of claim 16, wherein the heterostructure has a thickness of one unit cell U to 50 μm.

18. The Cr₅Te₈/WSe₂ heterostructure of claim 16, wherein the Cr₅Te₈ is a crystal grown on monolayer WSe₂ and the Cr₅Te₈ crystals are self-aligned such that an edge of Cr₅Te₈ crystal is parallel to an edge of the monolayer WSe₂.

19. The Cr₅Te₈/WSe₂ heterostructure of claim 16, wherein the Cr₅Te₈ is a crystal grown on monolayer WSe₂ and the Cr₅Te₈ crystals are self-aligned such that an edge of Cr₅Te₈ crystal is at an angle >0° relative to an edge of the monolayer WSe₂.

20. The Cr₅Te₈/WSe₂ heterostructure of claim 19, wherein the Cr₅Te₈ is a crystal grown on monolayer WSe₂ and the Cr₅Te₈ crystals are self-aligned such that the edge of Cr₅Te₈ crystal is 60° relative to the edge of the monolayer WSe₂.
